(19) United States
(12) Patent Application Publication
(10) Pub. No.: US 2014/0042517 A1
(43) Pub. Date: Feb. 13, 2014

(54) SEMICONDUCTOR MEMORY DEVICE AND MANUFACTURING METHOD THEREOF

(71) Applicant: KABUSHIKI KAISHA TOSHIBA, Tokyo (JP)

(72) Inventor: Kenji AOYAMA, Yokohama-Shi (JP)

(73) Assignee: KABUSHIKI KAISHA TOSHIBA, Tokyo (JP)

(21) Appl. No.: 13/780,281

(22) Filed: Feb. 28, 2013

(30) Foreign Application Priority Data
Aug. 7, 2012 (JP) 2012-175029

(51) Int. Cl. H01L 29/66; H01L 29/788

(52) U.S. Cl. CPC H01L 29/66825; H01L 29/788
USPC 257/316; 438/264

(57) ABSTRACT

In accordance with an embodiment, a semiconductor memory device includes a substrate and a plurality of memory cells. The substrate includes a semiconductor layer on a surface thereof. Each the memory cell includes a laminated body with a tunnel insulating film and a floating gate on the tunnel insulating film, a gate insulating film on the laminated body, and a control gate on the gate insulating film. The laminated body is sequentially laminated on the semiconductor layer in a direction vertical to the surface of the substrate for N (a natural number equal to or above 2) times. A dimension of the floating gate in the lowermost layer is at least partially smaller than a dimension of the floating gate in each of second and subsequent layers in at least one of a first direction parallel to the surface of the substrate and a second direction crossing the first direction.

### CROSS REFERENCE TO RELATED APPLICATIONS

This application is based upon and claims the benefit of priority from the prior Japanese Patent Application No. 2012-175029, filed on Aug. 7, 2012, the entire contents of which are incorporated herein by reference.

### FIELD

Embodiments described herein relate generally to a semiconductor memory device and a manufacturing method thereof.

### BACKGROUND

The capacity enlargement of nonvolatile semiconductor memory devices such as an NAND flash memory has been achieved on a daily basis by miniaturization and realization of multiple levels and, because of this, various cell structures have been suggested.

Expanding a write window has been demanded for further capacity enlargement in the future.

### BRIEF DESCRIPTION OF THE DRAWINGS

In the accompanying drawings,

FIG. 1A is a cross-sectional view showing an example of a memory cell having a lamination layer floating gate (FG) structure as a reference example;

FIG. 1B shows an equivalent circuit of FIG. 1A;

FIG. 2 is a plan view showing an example of the configuration of the memory according to the first embodiment;

FIG. 3 is a cross-sectional perspective view of the memory shown in FIG. 2;

FIG. 4 is a cross-sectional perspective view showing a modification of the embodiment depicted in FIG. 3;

FIG. 5A to FIG. 5D are cross-sectional perspective views for explaining a manufacturing method of the memory shown in each of FIG. 2 to FIG. 4;

FIG. 6 is a cross-sectional perspective view showing an outline configuration of a memory according to a second embodiment;

FIG. 7 is a cross-sectional perspective view showing a modification of the embodiment depicted in FIG. 6;

FIG. 8A to FIG. 8E are cross-sectional perspective views for explaining a manufacturing method of the memory depicted in FIG. 6 and FIG. 7:

FIG. 9A to FIG. 9D are cross-sectional views for explaining a relationship between a stop position of half etching and sizes and shapes of FGs in upper and lower layers shown in FIG. 8B;

FIG. 10 is a cross sectional perspective view showing an outline configuration of a memory according to a third embodiment;

FIG. 11 is a cross-sectional perspective view showing a modification of the embodiment depicted in FIG. 10;

FIG. 12A to FIG. 12E are cross-sectional perspective view for explaining a manufacturing method of the memory depicted in FIG. 10 and FIG. 11;

FIG. 13 is a cross-sectional perspective view showing an outline configuration of a memory according to a fourth embodiment;

FIG. 14 is a cross-sectional perspective view showing a modification of the embodiment depicted in FIG. 13;

FIG. 15A to FIG. 15E are cross-sectional perspective views for explaining a manufacturing method of the memory depicted in FIG. 13 and FIG. 14; and

FIG. 16A to FIG. 16D are cross-sectional views for explaining a relationship between a stop position of half etching and sizes and shapes of FGs in upper and lower layers shown in FIG. 8B.

### DETAILED DESCRIPTION

In accordance with an embodiment, a semiconductor memory device includes a substrate and a plurality of memory cells. The substrate includes a semiconductor layer on a surface thereof. Each the memory cell includes a laminated body with a tunnel insulating film and a floating gate on the tunnel insulating film, a gate insulating film on the laminated body, and a control gate on the gate insulating film. The laminated body is sequentially laminated on the semiconductor layer in a direction vertical to the surface of the substrate for N (a natural number equal to or above 2) times. A dimension of the floating gate in the lowermost layer is at least partially smaller than a dimension of the floating gate in each of second and subsequent layers in at least one of a first direction parallel to the surface of the substrate and a second direction crossing the first direction.

Embodiments will now be explained with reference to the accompanying drawings. Like components are provided with like reference signs throughout the drawings and repeated descriptions thereof are appropriately omitted. It is to be noted that an NAND flash memory (which will be also simply referred to as a “memory” hereinafter) will be described hereinafter, but the present invention is not restricted thereto and can be applied to any other memory having floating gates other than the NAND flash memory.

### (1) Coupling Ratio and Write Window

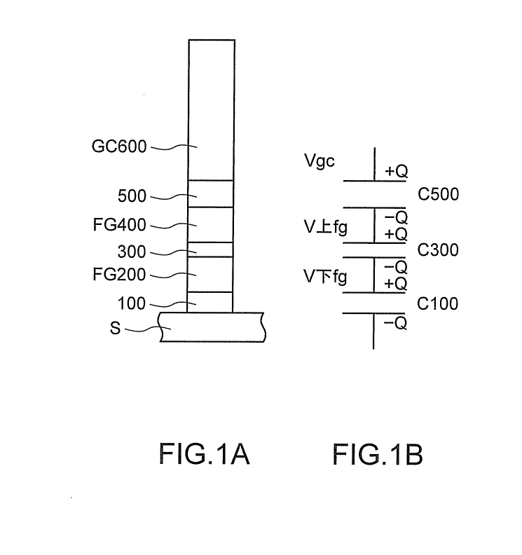

Before explaining the embodiments, a relationship between a coupling ratio and a write window will be described with reference to FIGS. 1A and 1B.

FIG. 1A is a cross-sectional view showing an example of a memory cell having a lamination layer FG configuration as a reference example. The memory cell shown in FIG. 1A has a double FG configuration in which a first insulating film 100, a lower layer floating gate (which will be appropriately referred to as “FG” hereinafter) 200, a second insulating film 300, an upper layer FG 400, a gate insulating film 500, and a gate conductor (which will be appropriately referred to as “GC” hereinafter) 600 are sequentially laminated on a semiconductor substrate S.

When the first insulating film 100, the second insulating film 300, and the gate insulating film 500 in the memory cell in FIG. 1A are considered as three capacitors and an equivalent circuit of FIG. 1A is drawn, this circuit is as shown in FIG. 1B.

Here, in regard to each capacitor, when a relationship between an electric charge Q, an electrostatic capacity C, and application voltages Vgc, Vupperfg, and Vlowerfg is considered, the following three expressions are achieved:

Q=Cipd×(Vgc−Vupperfg) Expression (1)

Q=Cifd×(Vupperfg−Vlowerfg) Expression (2)

Q=Ctnl×Vlowerfg Expression (3).

When Expressions (1) to (3) are solved with respect to Vupperfg and Vlowerfg, the following expressions can be obtained:

$$\begin{matrix}Vupperfg = ( \frac{Call}{Ctnl} + \frac{Call}{Cifd} ) \times Vcg & Expression ( 4 ) \\ Vlowerfg = \frac{Call}{Ctnl} \times Vcg . & Expression ( 5 )\end{matrix}$$

Here, the following expressions are achieved:

$$\begin{matrix}Ctnl = ɛ ( C 100 ) \frac{S ( C 100 )}{Eot ( C 100 )} & Expression ( 6 ) \\ Cifd = ɛ ( C 300 ) \frac{S ( C 300 )}{Eot ( C 300 )} & Expression ( 7 ) \\ Cipd = ɛ ( C 500 ) \frac{S ( C 500 )}{Eot ( C 500 )} \\ and & Expression ( 8 ) \\ \frac{1}{Call} = \frac{1}{Ctnl} + \frac{1}{Cifd} + \frac{1}{Cipd} , & Expression ( 9 )\end{matrix}$$

where ε is a dielectric constant of an insulating film, S is an area of the insulating film, and Eot is an Equivalent oxide thickness.

In the lamination layer FG configuration in FIG. 1A, a coupling ratio is a ratio of application of a voltage to the FG when the voltage is applied to the GC 600. Since the coupling ratio of the upper layer FG is (Call/Ctnl+Call/Cifd) and the coupling ratio of the lower layer FG is (Ca11/Ctnl), values of these coupling ratios can be raised by increasing an area of the upper layer FG and reducing an area of the lower layer FG.

Thus, when a size of the upper layer FG is maintained in a substantially unchanged state and a size of the lower layer FG alone is reduced, each coupling ratio (an FG potential) can be increased while maintaining a parasitic capacity between cells adjacent to each other. As a result, a write window can be expanded. Several embodiments for realizing such a coupling ratio will now be described hereinafter.

### (2) First Embodiment

(a) Device Configuration

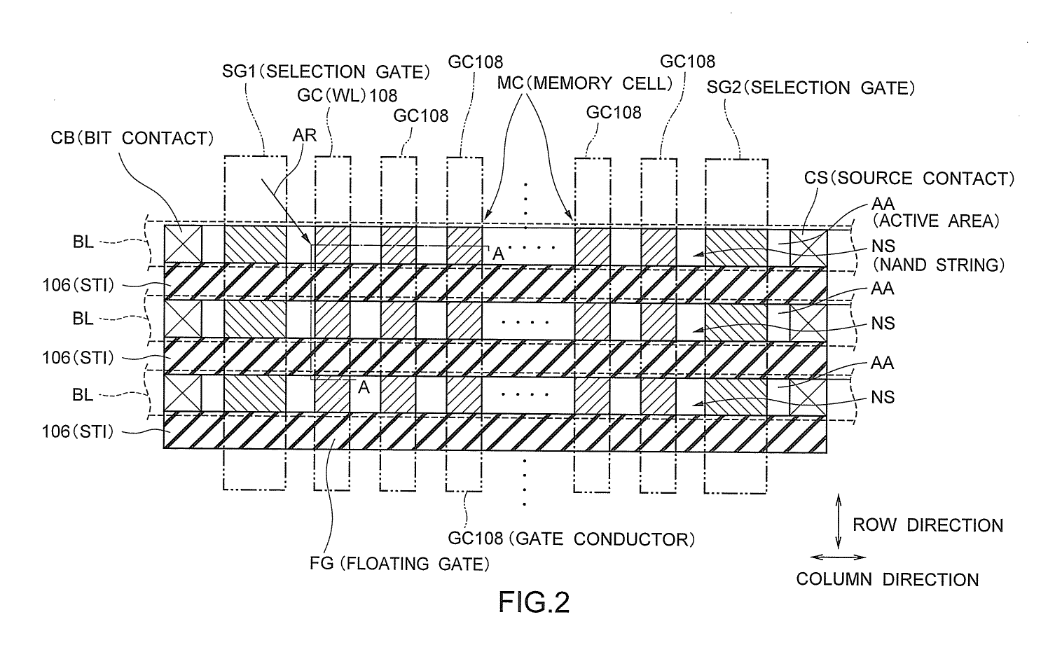

FIG. 2 is a plan view showing an example of a configuration of a memory according to a first embodiment. A memory according to this embodiment includes GCs 108 extending in a row direction and bit lines BL extending in a column direction. Each GC 108 and each bit line BL orthogonally cross each other in this embodiment. In this embodiment, each GC 108 corresponds to, e.g., a control gate. Furthermore, the column direction corresponds to, e.g., a first direction, and the row direction corresponds to, e.g., a second direction in this embodiment.

A memory cell MC is provided in accordance with each intersecting point of the GC 108 and the bit line BL. Each memory cell MC is formed in each active area AA extending in the column direction. Both each active area AA and each insulating film 106 as shallow trench insulation (STI) extend in the column direction. The active areas AA and the insulating films 106 are alternately arranged in the row direction at a predetermined pitch and provided in a stripe pattern.

The NAND flash memory includes NAND strings NS each of which is constituted of the plurality of memory cells MC connected in series along the column direction. Although three NAND strings NS are shown in FIG. 2, many NAND strings are usually provided. Each NAND string NS is connected to each bit line BL through a selection gate SG1 and also connected to a source through a selection gate SG2.

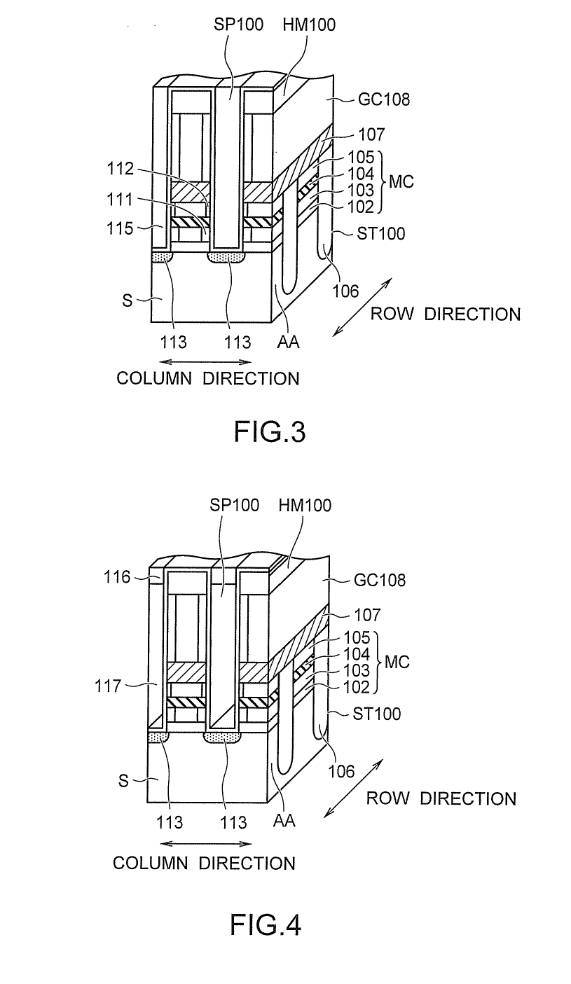

It is to be noted that the column direction and the row direction are expedient names, and these names can be counterchanged. FIG. 3 is a cross-sectional perspective view showing a cross section, which is taken along a cutting-plane line A-A in FIG. 2, and is viewed from a direction of an arrow AR1.

It is to be noted that, to simplify the explanation, the bit lines BL are omitted in the subsequent cross-sectional perspective views.

The memory cell MC is provided at each intersecting point of the GC 108 and the bit line BL on the active area AA of a semiconductor substrate S. The memory cell MC includes a first insulating film 102, a lower layer FG 103, a second insulating film 104, and an upper layer FG 105 which are sequentially laminated from a front surface side of the semiconductor substrate S. Each region between the memory cells MC in the row direction is the shallow trench isolation region, and the STI is formed of the insulating film 106. The GCs 108 extend on the memory cell MCs and the insulating films 106 via insulating films 107 along the row direction, and they are formed so as to be separated from each other in the column direction at a predetermined pitch. An insulating film 115 is formed in each region between the GCs 108, and an impurity diffusion layer 113 is formed on a surface layer of the semiconductor substrate S immediately below the insulating film 115. In this embodiment, both the first insulating film 102 and the second insulating film 104 correspond to, e.g., tunnel insulating films.

Of side surfaces of the lower layer FG 103 and the upper layer FG 105, oxides 111 and 112 are formed on sidewalls parallel to the row direction. A thickness of the oxide 111 is larger than that of the oxide 112. As a result, in the column direction, a size of the lower layer FG 103 is smaller than a size of the upper layer FG 105. In this embodiment, the oxides 111 and 112 correspond to, e.g., third and fourth insulating films.

FIG. 4 is a cross-sectional perspective view showing a modification of the embodiment depicted in FIG. 3. In the memory shown in FIG. 2 and FIG. 3, each space SP 100 between laminated bodies, each including the memory cell MC, the insulating film 107 and the GC 108, is filled with the insulating film 115. In the memory according to this modification, an insulating film 116 of poorer coverage is formed in the space SP 100, and a cavity 117 is thereby formed.

(b) Manufacturing Method

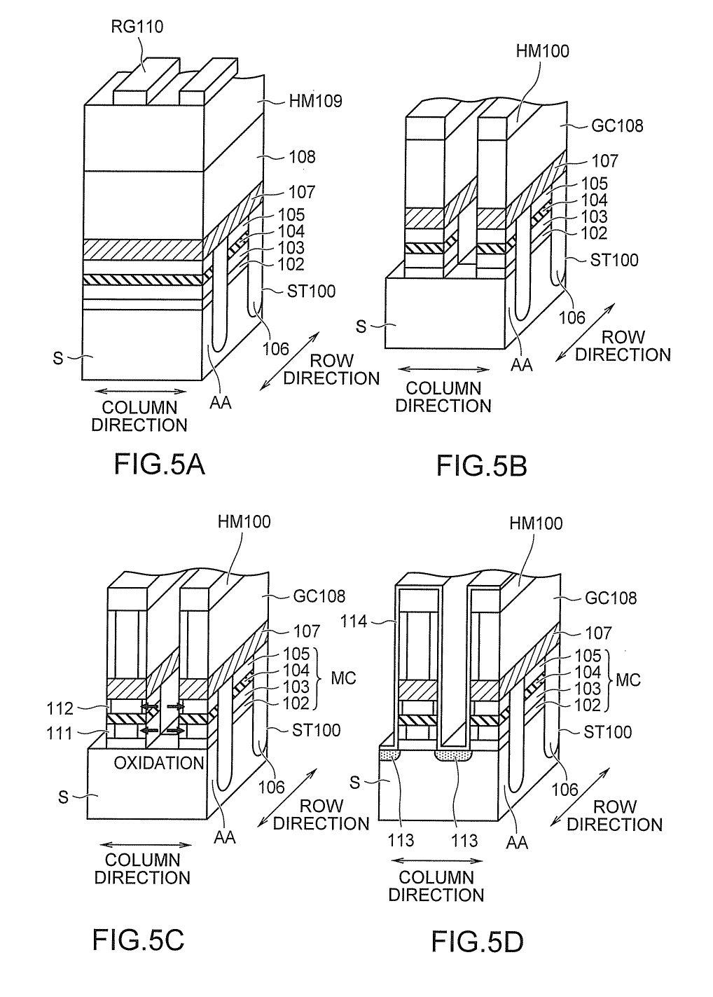

A manufacturing method of the memory shown in FIG. 2 to FIG. 4 will now be described with reference to FIG. 5A to FIG. 5D.

First, on the semiconductor substrate S, the insulating film 102, the lower layer FG 103, the insulating film 104, and the upper layer FG 105 are sequentially formed.

A material of the insulating film 102 is selected from, e.g., a silicon oxide film, a silicon oxynitride film, and a silicon nitride film.

Each of the lower layer FG 103 and the upper layer FG 105 is formed of a single layer or a laminated layer of non-doped polysilicon or B or P-doped polysilicon, a metal such as TiN, TaN, or W, or a silicide of these materials. As one of characteristics of the manufacturing method according to this embodiment, a material having a higher oxidation rate than the upper layer FG 105 is selected as the material of the lower layer FG 103.

A material of the insulating film 104 is selected from, e.g., a silicon oxide film, a silicon oxynitride film, a silicon nitride film, Al₂O₃, HfOₓ, TaOₓ, and La₂Oₓ.

Subsequently, a resist (not shown) for forming a hard mask (not shown) and the shallow trench isolation is formed on the upper layer FG 105, then a desired AA pattern is formed by photolithography, shallow trench isolation grooves ST 100 (see FIG. 5A) are formed by performing etching such as reactive ion etching (RIE). The shallow trench isolation grooves ST 100 are then filled with the insulating films 106 such as silicon oxide films, and flattening is carried out by chemical and mechanical polishing (CMP) or wet etching until an upper end of the upper layer 105 is exposed.

Then, each resist RG 110 which is used for forming the insulating film 107, a conductive film 108, the hard mask HM 109, and a GC pattern is sequentially formed, and then a desired GC pattern is formed by photolithography as shown in FIG. 5A.

A material of the insulating film 107 is selected from, e.g., a silicon oxide film, a silicon oxynitride film, a silicon nitride film, Al₂O₃, HfOₓ, TaOₓ, and La₂Oₓ. Furthermore, a material of the conductive film 108 is selected from, e.g., non-doped polysilicon or B or P-doped polysilicon, a metal such as TiN, TaN, W, Ni, or Co and a silicide of these materials.

Subsequently, the layers from the conductive film 108 to the insulating film 102 is etched by the RIE or the like, and the GC pattern is formed as shown in FIG. 5B.

Then, as shown in FIG. 5C, sidewalls of the lower layer FG 103 and the upper layer FG 105 along the row direction are oxidized by using thermal oxidation or plasma oxidation. At this time, since the material of the lower layer FG 103 has a higher oxidation rate than the material of the upper layer FG 105, a film thickness of the oxide 111 formed on the sidewall of the lower layer FG 103 is larger than a film thickness of the oxide 112 formed on the sidewall of the upper layer FG 105.

For example, the lower layer FG 103 is made of P-doped polysilicon, the upper layer FG 105 is made of B-doped polysilicon, the laminated body including the GC 108, the memory cell MC, and the insulating film 107 shown in FIG. 5B is formed, the RIE process is performed, and then heating is carried out in an oxidizing atmosphere at 100° C. to 400° C.

Since the P-doped polysilicon which is an n-type semiconductor has a higher number of electronic carriers than the B-doped polysilicon which is a p-type semiconductor, the P-doped polysilicon is apt to be oxidized by supplying oxygen to the electrons. Therefore, the P-doped polysilicon in the lower layer has a higher oxidization rate than the B-doped polysilicon in the upper layer, and hence a silicon oxide film formed on the sidewall of the P-doped polysilicon in the lower layer FG 103 is thicker than that of the B-doped polysilicon in the upper layer FG 105. As a result, a size of the lower layer FG 103 in the column direction is smaller than a size of the upper layer FG 105 in the column direction.

Then, impurities are implanted into the active area AA between the GCs 108 by implantation, diffusion layers 113 serving as a source and a drain are formed, and an insulating film 114 such as a silicon oxide film having a thickness of several nm which is thinner than a half of a pitch (which will be referred to as “HP” hereinafter) between the GC 108 is formed on the sidewalls of the memory cell MC, the insulating film 107, and the GC 108, as shown in FIG. 5D.

At last, the space SP 100 between the insulating films 114 is filled with the insulating film 115 such as a silicon oxide film, whereby the memory shown in FIG. 3 is provided. Furthermore, in place of filling the space SP 100 with the insulating film 115, the cavity 117 may be formed by forming the insulating film 116 having poorer coverage. As a result, the memory according to the modification shown in FIG. 4 is provided.

### (3) Second Embodiment

(a) Device Configuration

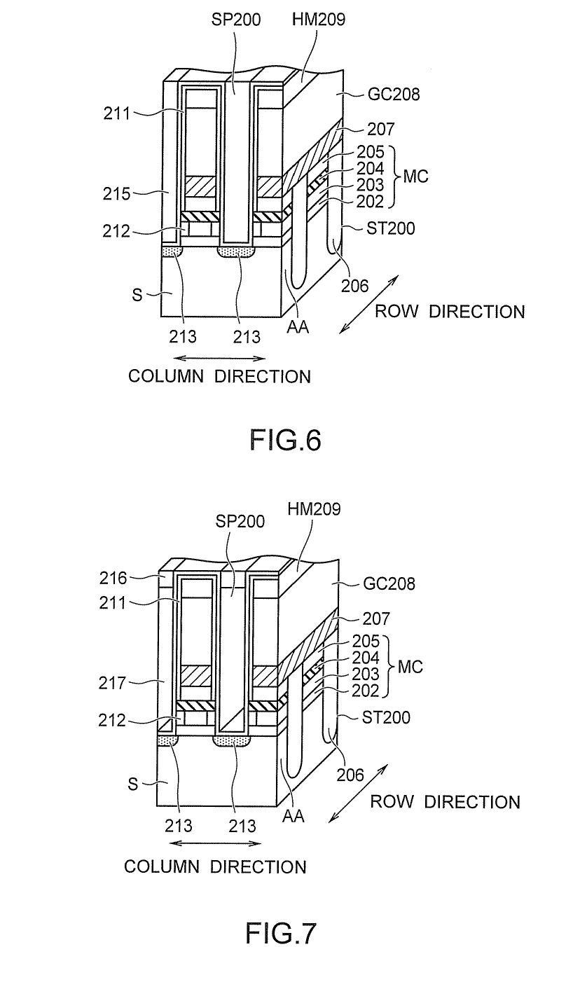

FIG. 6 is a cross-sectional perspective view showing an outline configuration of a memory according to a second embodiment. A relationship between the cross-sectional perspective view of FIG. 6 and a top view of the memory according to this embodiment is the same as the relationship between FIG. 2 and FIG. 3, and FIG. 6 relates to a cross section taken along a cutting-plane line A-A in FIG. 2. This point is likewise applied to later-described third and fourth embodiments.

As obvious from comparison with FIG. 3, the memory according to this embodiment is characterized in that the memory includes an insulating film 211 which is integrally formed from a sidewall of an upper layer FG 205 to a top face of a hard mask HM 209 in place of the oxide 112 formed on the sidewall of the upper layer FG 105 depicted in FIG. 3. A thickness of the insulating film 211 is smaller than that of a sidewall insulating film 212 of the lower layer FG 103. Other structures of the memory according to this embodiment correspond to those denoted by reference numerals in the first embodiment with 100 added thereto, and they are substantially equal to those in the memory shown in FIG. 2 and FIG. 3.

FIG. 7 is a cross-sectional perspective view showing a modification of the embodiment depicted in FIG. 6. In the memory shown in FIG. 6 a space SP 200 between laminated bodies, each including a memory cell MC, an insulating film 207, and a GC 208, is filled with an insulating film 215. In the memory according to this modification, an insulating film 216 of poorer coverage is formed on a sidewall of the space SP 200, whereby a cavity 217 is formed.

(b) Manufacturing Method

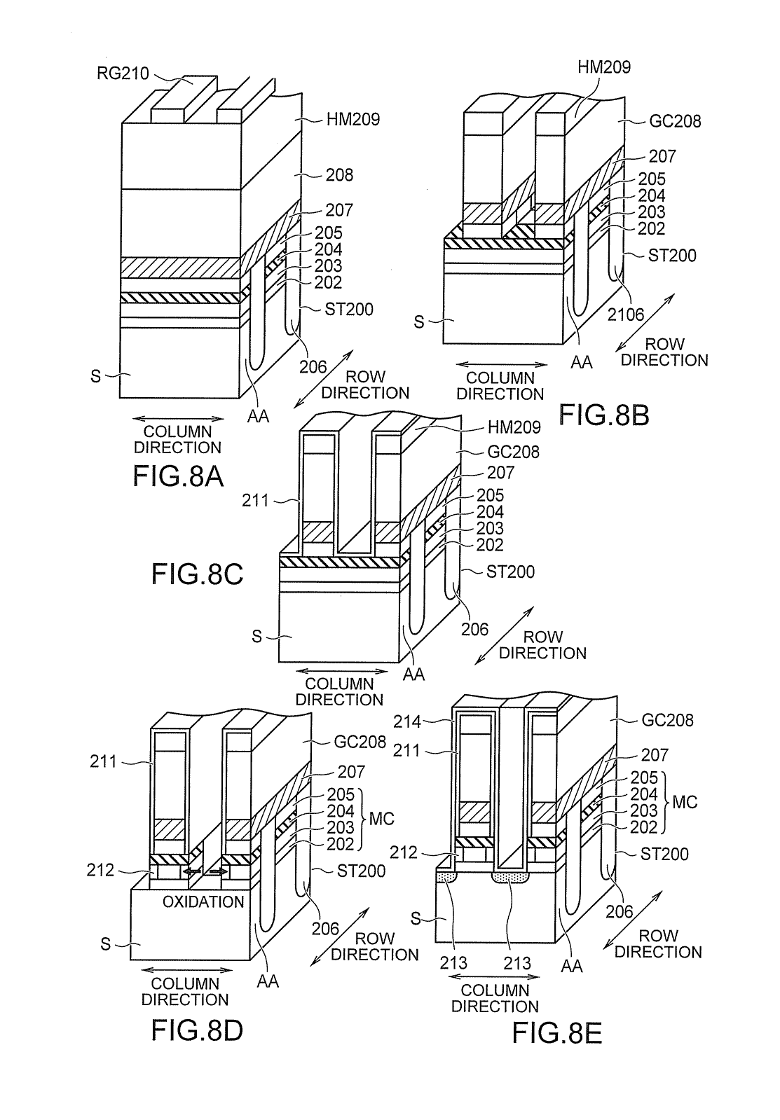

A manufacturing method of the memory shown in FIG. 6 and FIG. 7 will now be described with reference to FIG. 8A to FIG. 8E.

First, an insulating film 202, the lower layer FG 203, an insulating film 204, and the upper layer FG 205 are sequentially formed on a semiconductor substrate S.

A material of the insulating film 202 is selected from, e.g., a silicon oxide film, a silicon oxynitride film, and a silicon nitride film.

Each of the lower layer FG 203 and the upper layer FG 205 is formed of a single layer or a laminated layer of non-doped polysilicon or B or P-doped polysilicon, a metal such as TiN, TaN, or W, or a silicide of these materials. However, in this embodiment, as different from the lower layer FG 103 and the upper layer FG 105 shown in FIG. 3 and FIG. 4, the material of the lower layer FG 203 does not have to be different from the material of the upper layer FG 205 in particular in terms of an oxidation rate.

A material of the insulating film 204 is selected from, e.g., a silicon oxide film, a silicon oxynitride film, a silicon nitride film, Al₂O₃, HfOₓ, TaOₓ, and La₂Oₓ.

Subsequently, a resist (not shown) for forming a hard mask (not shown) and shallow trench isolation is formed on the upper layer FG 205, then a desired AA pattern is formed by photolithography, shallow trench isolation grooves ST 200 (see FIG. 8A) are formed by performing etching such as RIE. The shallow trench isolation grooves ST 200 are then filled with the insulating films 206 such as silicon oxide films, and flattening is carried out by CMP or wet etching until an upper end of the upper layer 205 is exposed.

Subsequently, each resist RG 210 which is used for forming the insulating film 207, a conductive film 208, the hard mask HM 209, and a GC pattern is sequentially formed, and then a desired GC pattern is formed by photolithography as shown in FIG. 8A.

A material of the insulating film 207 is selected from, e.g., a silicon oxide film, a silicon oxynitride film, a silicon nitride film, Al₂O₃, HfOₓ, TaOₓ, and La₂Oₓ. Furthermore, a material of the conductive film 208 is selected from, e.g., non-doped polysilicon or B or P-doped polysilicon, a metal such as TiN, TaN, W, Ni, or Co and a silicide of these materials.

Then, as shown in FIG. 8B, half etching is carried out based on RIE or the like until any position in the range from an upper end of the upper layer FG 205 to a lower end of the lower layer FG 203 is reached, and the insulating film 211 is formed on the entire surface as shown in FIG. 8C. Here, the insulating film 211 is made of an oxidation-resistant material such as a silicon nitride film in such a manner that this film becomes thinner than a later-described sidewall oxide 212 (see FIG. 8D). In this embodiment, the insulating film 211 corresponds to, e.g., a fourth insulating film.

Thereafter, as shown in FIG. 8D, the etching is again carried out by RIE or the like until at least the insulating film 202 is exposed, the sidewall of the lower layer FG 203 is oxidized by thermal oxidation or plasma oxidation, and the sidewall oxide 212 is thereby formed.

As described above, when the insulating film 211 is made of an oxidation-resistant material such as a silicon nitride film, the sidewall of the upper layer FG 205 can be prevented from being further oxidized at a time of oxidizing the sidewall of the lower layer FG 203. Further, when the thickness of the insulating film 211 is reduced to be smaller than an oxidation amount of the sidewall oxide 212 of the lower layer FG 203, a dimension of a bottom surface of the lower layer FG 203 can be set smaller than a dimension of a top face of the upper layer FG 205. As a result, a coupling ratio can be increased.

Thereafter, as shown in FIG. 8E, like the first embodiment, impurities are implanted, diffusion layers 213 serving as a source and a drain are formed, and an insulating film 214 such as a silicon oxide film having a thickness of several nm which is thinner than the HP is formed on the sidewalls. At last, the space SP 200 between laminated bodies each including the memory cell MC, the insulating film 207, and the GC 208 is filled with the insulating film 215 such as a silicon oxide film, whereby the memory shown in FIG. 6 is provided. Furthermore, in place of filling the space SP 200 with the insulating film 215, the cavity 117 may be formed by forming the insulating film 216 having poorer coverage. As a result, the memory according to the modification shown in FIG. 7 is provided.

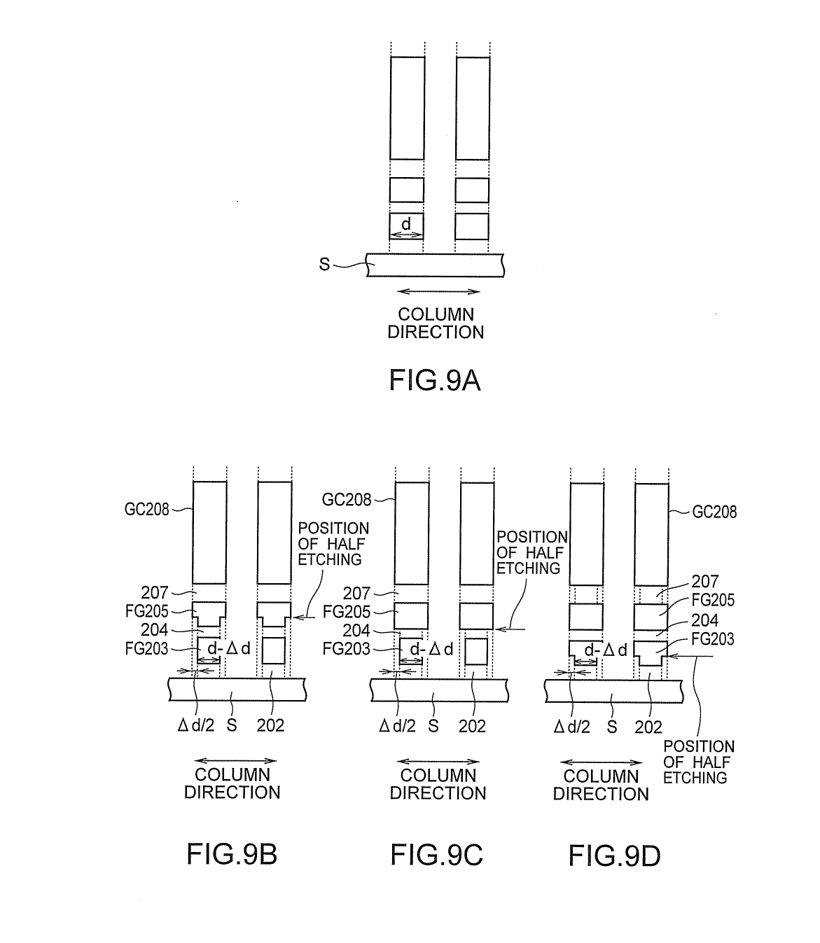

In this embodiment, sizes and shapes of the upper layer FG 205 and the lower layer FG 203 vary depending on a position at which the half etching is stopped between the upper end of the upper layer FG 205 and the lower end of the lower layer FG 203. This point will now be specifically explained with reference to FIGS. 9A to 9D.

Each of FIG. 9A to FIG. 9D is a cross-sectional view obtained by cutting a memory having a double FG configuration along a cutting-plane line parallel to the bit lines (in the column direction). As a memory shown in FIG. 9A, a reference example where members from the tunnel insulating film to the GC immediately above the semiconductor substrate S have the same size is illustrated.

FIG. 9B to FIG. 9D show examples of the memory according to this embodiment, and respective examples are illustrated in which the stop position of the half etching is varied in the process shown in FIG. 8B. FIG. 9B shows a situation where the half etching is stopped at a halfway position between the upper end and the lower end of the upper layer FG 205, FIG. 9C shows a situation where the half etching is stopped at a halfway position between the upper end and the lower end of the insulating film 204 in the upper layer, and FIG. 9D shows a situation where the half etching is stopped at a halfway position between the upper end and the lower end of the lower layer FG 203.

In the case of FIG. 9B, a step is produced on the sidewall of the upper layer FG 205, a size of a top face of the FG 205 is different from a size of a bottom face of the FG 205. The second insulating film 204, the lower layer FG 203, and the first insulating film 202 have the same size as the size of the bottom size of the upper layer FG 205 in the column direction. When the sizes of the opposed surfaces of the upper and lower FG 205 and FG 203 are smaller than the size of the top face of upper layer FG 205 in this manner, there is an advantage that an electric field can be easily applied.

In the case of FIG. 9C, although there is no step on the sidewalls of both the upper layer FG 205 and the lower layer FG 203, the size of the top face of the lower layer FG 203 facing the bottom face of the upper layer FG 205 is the same as that in FIG. 9B and smaller than those in the reference example of FIG. 9A and in FIG. 9D.

In the case of FIG. 9D, although the size of the top face of the lower layer FG 203 is the same as the sizes of the top face and the bottom face of the upper layer FG 205 facing the top face of the FG 203, a step is produced on the sidewall of the lower layer FG 203, the size of the bottom face of the lower layer FG 203 is smaller than the size of the top face of the FG203, and the size of the lower layer FG 203 is partially small on the semiconductor substrate S side.

In each of FIG. 9B to FIG. 9D, although the size of the top face of the upper layer FG 205 is the same as that in the reference example, the size of the bottom face of the lower layer FG 203 is smaller than the size of the top face of the upper layer FG 205, and hence a coupling ratio can be increased. Although a value of a difference Δd in size shown in each of FIG. 9B to FIG. 9D is allowed as long as it does not affect transistor characteristics, it is desirable for Δd/2 to fall within the range of approximately 5% to approximately 20% of the top face size of the upper layer FG 205 at each end portion in the column direction.

### (4) Third Embodiment

(a) Device Configuration

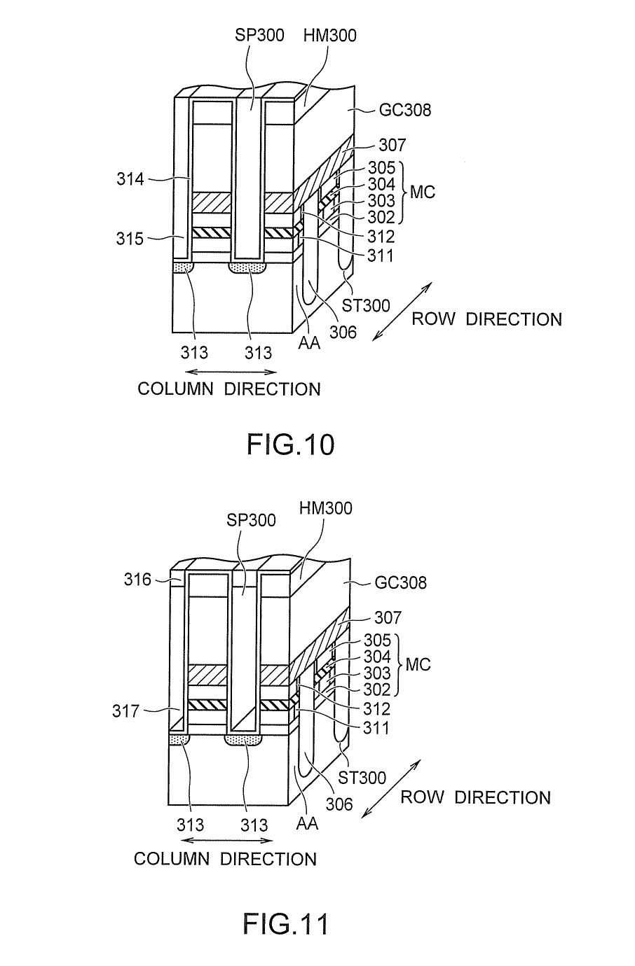

FIG. 10 is a cross-sectional perspective view showing an outline configuration of a memory according to the third embodiment. As obvious from comparison with FIG. 3, the memory according to this embodiment is characterized in that oxides 311 and 312 are formed on sidewalls parallel to the column direction, of side surfaces of a lower layer FG 303 and an upper layer FG 305, respectively and that the oxide 311 is formed with a thickness larger than that of the oxide 312. As a result, in the row direction, a size of the lower layer FG 303 is smaller than that of the upper layer FG 305.

Other structures of the memory according to this embodiment correspond to those with reference numerals of the first embodiment with 200 added thereto, and they are substantially equal to those in the memory shown in FIG. 2 and FIG. 3.

FIG. 11 is a cross-sectional perspective view showing a modification of the embodiment depicted in FIG. 10. In the memory shown in FIG. 11 a space SP 300 between laminated bodies, each including a memory cell MC, an insulating film 307, and a GC 308 is filled with an insulating film 315. In the memory according to this modification, an insulating film 316 of poorer coverage is formed on a sidewall of the space SP 300 whereby a cavity 317 is formed.

(b) Manufacturing Method

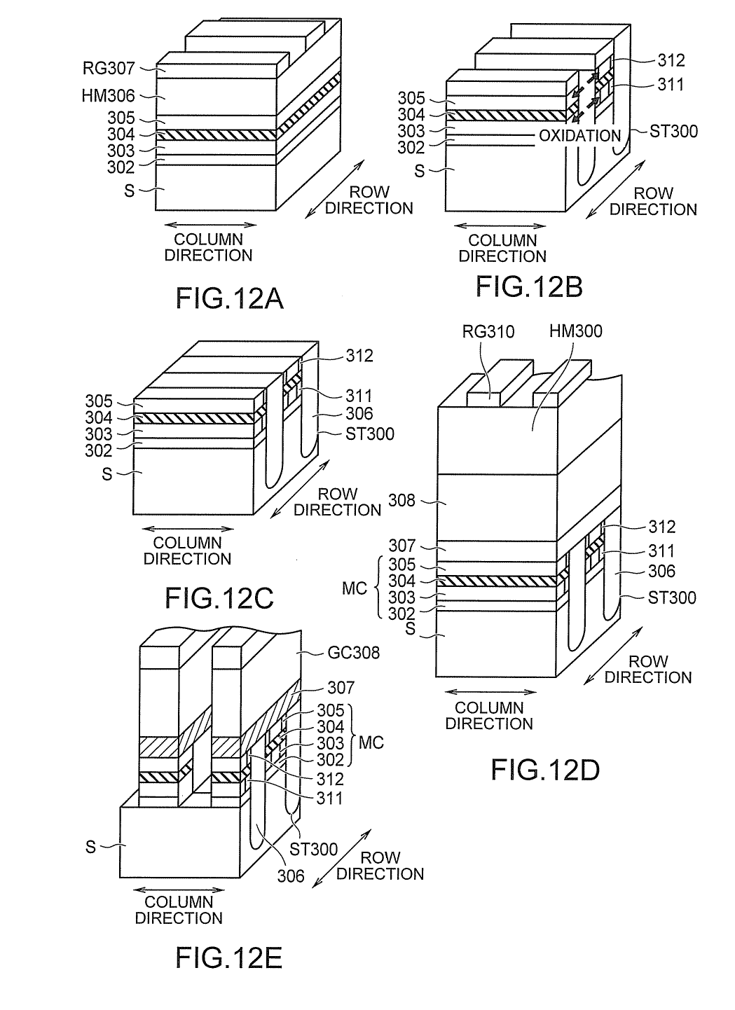

A manufacturing method of the memory shown in FIG. 10 and FIG. 11 will now be described with reference to FIG. 12A to FIG. 12E.

First, an insulating film 302, the lower layer FG 303, an insulating film 304, and the upper layer FG 305, a hard mask HM 306, and a resist RG 307 are formed on a semiconductor substrate S, and a desired AA pattern is formed by the photolithography as shown in FIG. 12A.

A material of the insulating film 302 is selected from, e.g., a silicon oxide film, a silicon oxynitride film, and a silicon nitride film.

Each of the lower layer FG 303 and the upper layer FG 305 is formed of a single layer or a laminated layer of non-doped polysilicon or B or P-doped polysilicon, a metal such as TiN, TaN, or W, or a suicide of these materials. In this embodiment, as a material of the lower layer FG 303, a material having an oxidation rate higher than that of the upper layer FG 305 is selected.

A material of the insulating film 304 is selected from, e.g., a silicon oxide film, a silicon oxynitride film, a silicon nitride film, Al₂O₃, HfOₓ, TaOₓ, and La₂Oₓ.

Then, each shallow trench isolation groove ST 300 is formed by etching such as RIE, and sidewalls of the lower layer FG 303 and the upper layer FG 305 are oxidized by thermal oxidation or plasma oxidation as shown in FIG. 12B. At this time, since the material of the lower layer FG 303 has a higher oxidation rate than the material of the upper layer FG 305, a thickness of the oxide 311 formed on the sidewall of the lower layer FG 303 is larger than a thickness of the oxide 312 formed on the sidewall of the upper layer FG 305.

For example, assuming that the lower FG 303 is made of P-doped polysilicon and the upper layer FG 305 is made of B-doped polysilicon, since the P-doped polysilicon as an n-type semiconductor has a larger number of electron carriers than the B-doped polysilicon which is a p-type semiconductor, the P-doped polysilicon is apt to be oxidized by supplying oxygen to the electrons. Therefore, the P-doped polysilicon has a high oxidization rate, and hence a silicon oxide film formed on the sidewall of the lower layer FG 303 made of the P-doped polysilicon is thicker than that of the upper layer FG 305 made of the B-doped polysilicon.

Then, as shown in FIG. 12C, the shallow trench isolation grooves ST 300 are filled with the insulating films 306 such as silicon oxide films, and flattening is carried out by CMP or wet etching until an upper end of the upper layer 305 is exposed. Subsequently, the insulating film 307, the conductive film 308, the hard mask HM 300, and a resist RG 310 forming a GC pattern are formed, and then a desired GC pattern is formed by photolithography as shown in FIG. 12D.

Here, the insulating film 307 is formed by using a silicon oxide film, a silicon oxynitride film, a silicon nitride film, Al₂O₃, HfOₓ, TaOₓ, La₂Oₓ, and others, and the conductive film 308 is made of non-doped polysilicon or B or P-doped polysilicon, a metal such as TiN, TaN, W, Ni, or Co or a silicide of these materials.

Subsequently, the layers from the conductive film 308 to the insulating film 302 are selectively removed by RIE or the like, whereby a GC pattern is formed as shown in FIG. 12E.

Then, impurities are implanted into the active area AA between laminated bodies, each including the memory cell MC, the insulating film 307 and the GC 308, diffusion layers 313 that serve as a source and a drain are formed, and an insulating film 314 (see FIG. 10) such as a silicon oxide film having a thickness of several nm which is thinner than the HP is formed on a sidewall of each laminated body including the memory cell MC, the insulating film 307, and the GC 308.

At last, the space SP 300 between the laminated bodies, each including the memory cell MC, the insulating film 307 and the GC 308, is filled with the insulating film 315 such as a silicon oxide film, thus the memory shown in FIG. 10 is provided. Furthermore, in place of filling the space SP 300 with the insulating film 315, the cavity 317 may be formed by forming the insulating film 316 having poorer coverage. As a result, the memory according to the modification shown in FIG. 11 is provided.

### (5) Fourth Embodiment

(a) Device Configuration

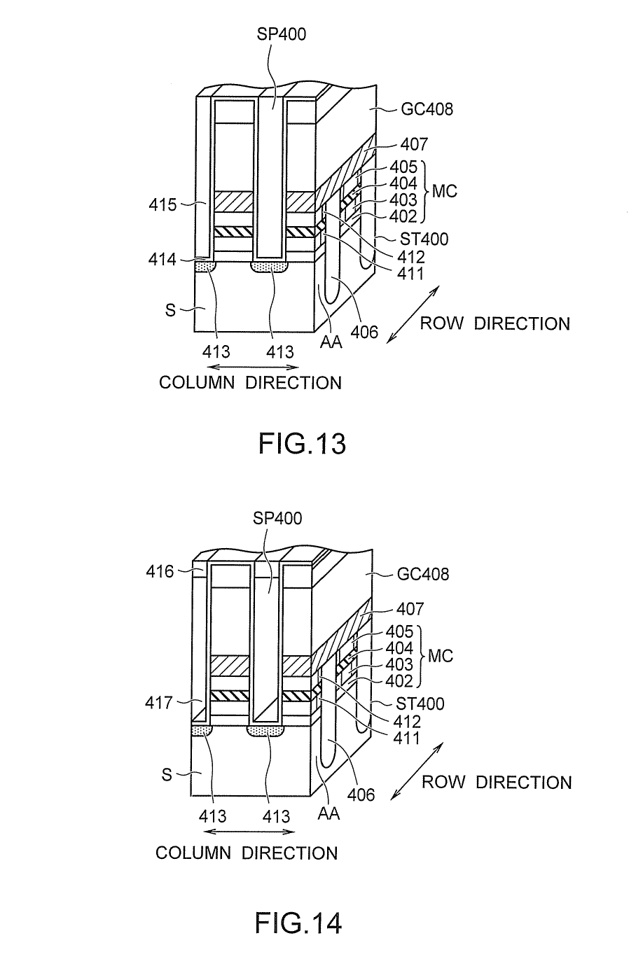

FIG. 13 is a cross-sectional perspective view showing an outline configuration of a memory according to a fourth embodiment. As obvious from comparison with FIG. 10, the memory according to this embodiment is characterized in that the memory includes an insulating film 412 in place of the oxide 312 formed on the sidewall of the upper layer FG 305 in FIG. 10. A thickness of the insulating film 412 is smaller than that of a sidewall insulating film 411 of a lower layer FG 403. Other structures of the memory according to this embodiment correspond to those denoted by reference numerals of the third embodiment with 100 added thereto, and they are substantially equal to those in the memory shown in FIG. 10.

FIG. 14 is a cross-sectional perspective view showing a modification of the embodiment depicted in FIG. 13. In the memory shown in FIG. 14 a space SP 400 between laminated bodies, each including a memory cell MC, an insulating film 407 and a GC 408, is filled with an insulating film 415. In the memory according to this modification an insulating film 416 having poorer coverage is formed on a sidewall of the space SP 400, whereby a cavity 417 is formed.

(b) Manufacturing Method

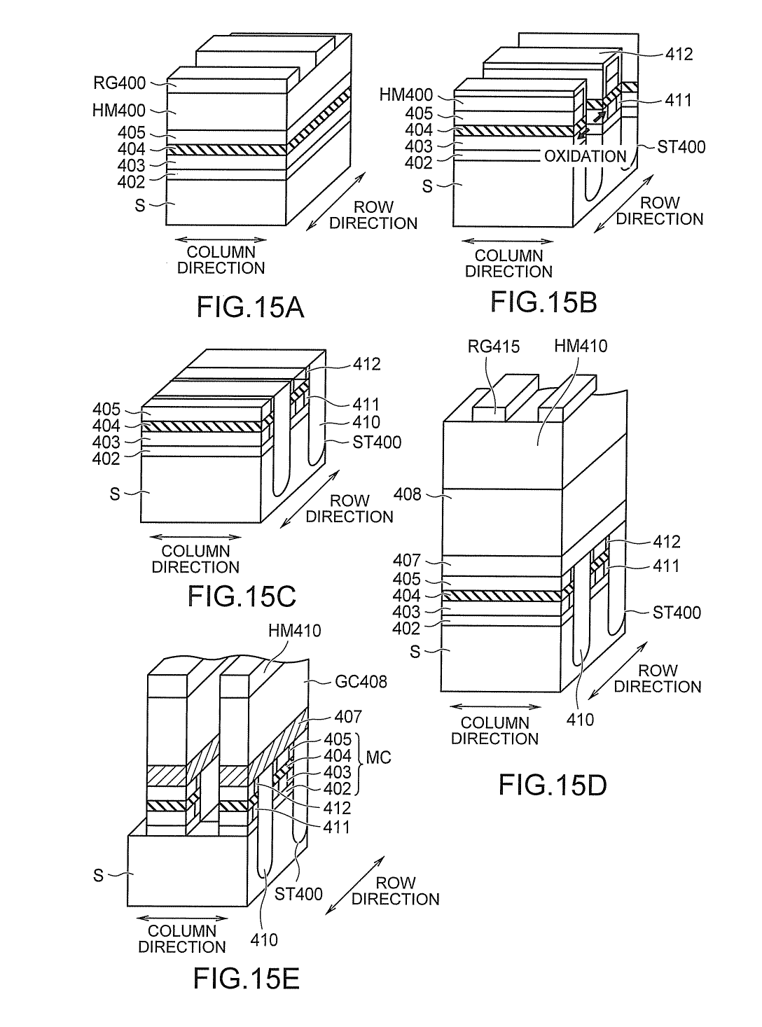

A manufacturing method of the memory shown in FIG. 13 and FIG. 14 will now be described with reference to FIG. 15A to FIG. 15E.

First, an insulating film 402, the lower layer FG 403, an insulating film 404, an upper layer FG 405, a hard mask HM 400, and a resist RG 400 are formed on a semiconductor substrate S, and a desired AA pattern is formed by photolithography as shown in FIG. 15A.

A material of the insulating film 402 is selected from, e.g., a silicon oxide film, a silicon oxynitride film, and a silicon nitride film. Each of the lower layer FG 403 and the upper layer FG 405 is formed of a single layer or a laminated layer of non-doped polysilicon or B or P-doped polysilicon, a metal such as TiN, TaN, or W, or a silicide of these materials. In this embodiment, as different from the lower layer FG 303 and the upper layer FG 305 shown in FIG. 10 and FIG. 11, the material of the lower layer FG 403 does not have to be different from the material of the upper layer FG 405 in particular in terms of an oxidation rate. A material of the insulating film 404 is selected from, e.g., a silicon oxide film, a silicon oxynitride film, a silicon nitride film, Al₂O₃, HfOₓ, TaOₓ, and La₂Oₓ.

Subsequently, half etching is carried out by RIE or the like until any position in at least the range from an upper end of the upper layer FG 405 to a lower end of the lower layer FG 403 is reached, and then the insulating film 412 is formed on the entire surface as shown in FIG. 15B. Here, the insulating film 412 is made of an oxidation-resistant material such as a silicon nitride film so as to be thinner than the later-described sidewall oxide 411 (see FIG. 13).

Thereafter, the etching is again carried out by RIE or the like until an arbitrary position in the semiconductor substrate S is reached, each shallow trench isolation groove ST 400 is formed, a sidewall of the lower layer FG 403 is oxidized by thermal oxidation or plasma oxidation, and the sidewall oxide 411 is formed.

Here, when the insulating film 411 is made of an oxidation-resistant material such as a silicon nitride film, the sidewall of the lower layer FG 403 can be prevented from being further oxidized in an oxidation process of this sidewall, and a thickness of the insulating film 411 is reduced to be smaller than an oxidation amount of the sidewall oxide 412 of the lower layer FG 403. As a result, a dimension of a bottom surface of the lower layer FG 403 can be decreased to be smaller than a dimension of a top face of the upper layer FG 405, and a coupling ratio can be raised.

Then, as shown in FIG. 15C, the shallow trench isolation grooves ST 400 are filled with an insulating films 410 such as silicon oxide films, and flattening is carried out by CMP or wet etching until an upper end of the upper layer 405 is exposed.

Subsequently, the insulating film 407, the conductive film 408, a hard mask HM 410, and a resist RG 415 which is used for forming a GC pattern are sequentially formed, and then a desired GC pattern is formed by photolithography as shown in FIG. 15D.

A material of the insulating film 407 is selected from, e.g., a silicon oxide film, a silicon oxynitride film, a silicon nitride film, Al₂O₃, HfOₓ, TaOₓ, La₂Oₓ, and others. The conductive film 413 is made of non-doped polysilicon or B or P-doped polysilicon, a metal such as TiN, TaN, W, Ni, or Co, or a suicide of these materials.

Subsequently, the layers from the conductive film 408 to the insulating film 402 are selectively removed by RIE or the like, whereby a GC pattern is formed as shown in FIG. 15E.

Then, impurities are implanted into the active area AA between laminated bodies, each including the memory cell MC, the insulating film 407 and the GC 408, diffusion layers 413 that serve as a source and a drain are formed, and an insulating film 414 (see FIG. 13) such as a silicon oxide film having a thickness of several nm which is thinner than the HP is formed on a sidewall of each laminated body including the memory cell MC, the insulating film 407, and the GC 408.

At last, the space SP 400 between the laminated bodies, each including the memory cell MC, the insulating film 407 and the GC 408, is filled with the insulating film 415 such as a silicon oxide film, thus the memory shown in FIG. 13 is provided. Furthermore, in place of filling the space SP 400 with the insulating film 415, the cavity 417 may be formed by forming the insulating film 416 having poorer coverage. As a result, the memory according to the modification shown in FIG. 14 is provided.

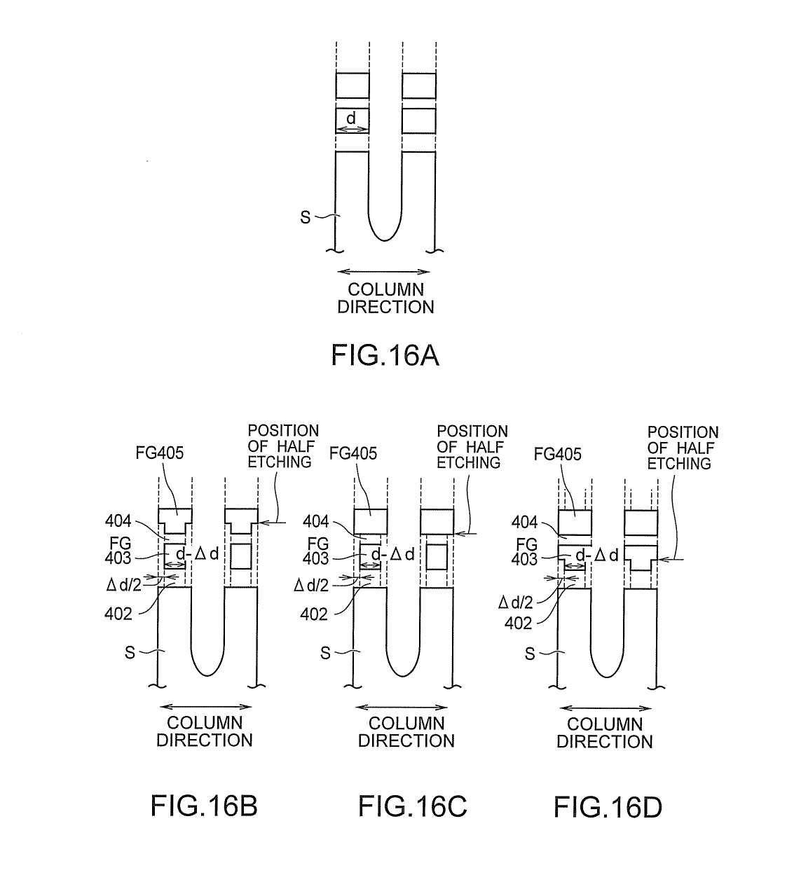

In this embodiment, sizes and shapes of the upper layer FG 405 and the lower layer FG 403 vary in accordance with a position where the half etching in the process shown in FIG. 15B is stopped in the range from the upper end of the upper layer FG 405 to the lower end of the lower layer FG 403. This point will now be specifically described with reference to FIG. 16A to FIG. 16D.

Each of FIG. 16A to FIG. 16D is a cross-sectional view obtained by cutting a memory of a double FG configuration along a cutting-plane line parallel to the GCs (in the row direction). As reference examples two memories are shown in FIG. 16A, in which sizes in the row direction are the same in a range from a tunnel insulating film to the GC immediately above the semiconductor substrate S.

FIG. 16B to FIG. 16D show examples of the memory according to this embodiment. In these figures respective examples are illustrated in which the stop position of the half etching is changed in the process shown in FIG. 15B. FIG. 16B shows a situation where the half etching is stopped at a halfway position between the upper and lower ends of the upper layer FG 405, FIG. 16C shows a situation where the half etching is stopped at a halfway position between the upper and lower ends of the insulating film 404 in the upper layer, and FIG. 16D shows a situation where the half etching is stopped at a halfway position between the upper and lower ends of the lower layer FG 403.

In the case of FIG. 16B, a step is produced on the sidewall of the upper layer FG 405, and a size of the top face of the FG 405 is different from a size of the bottom face of the FG 405. The insulating film 404, the lower layer FG 403, and the insulating film 402 have the same size as the size of the bottom face of the upper layer FG 405 in the row direction. In this manner, when the sizes of the upper and lower floating gates FG 405 and FG 403 are partially different from each other and the size of the lower layer FG 402 is smaller than the size of the top face of the upper layer FG 405, there can be obtained an advantage that an electric field can be easily applied.

In the case of FIG. 16C, although there is no step on the sidewalls of both the upper layer FG 405 and the lower layer FG 403, the size of the top face of the lower layer FG 403 facing the bottom face of the upper layer FG 405 is smaller than that of the reference example in FIG. 16A and that in FIG. 16D.

In the case of FIG. 16D, although the size of the top face of the lower layer FG 403 is the same as the size of the bottom face of the upper layer FG 405 facing the top face of the lower layer FG 403, a step is formed on the sidewall of the lower layer FG 403, the size of the bottom face of the lower layer FG 403 is smaller than the size of the top face of the lower layer FG 403, and the size of the lower layer FG 403 is partially small in the row direction.

In each of FIG. 16B to FIG. 16D, although the size of the top face of the upper layer FG 405 is equal to that in the reference example, the size of the bottom face of the lower layer FG 403 is smaller than the size of the top face of the upper layer FG 405, and hence a coupling ratio can be raised. Although a value of a difference Δd in size shown in each of FIGS. 16B to 16D is allowed as long as it does not affect transistor characteristics, it is desirable for Δd/2 to fall within the range of approximately 5% to approximately 20% of the top face size of the upper layer FG 405 at each end portion in the row direction.

According to the memory of each of the foregoing embodiments, the size of the lower layer FG is formed to be at least partially smaller than the size of the upper layer FG, the coupling ratio is thereby raised, and hence the write window can be enlarged.

Additionally, according to the memory of each of the foregoing modifications, the cavity is formed in the region between the GCs, a capacity between the GCs can thus be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, in each of the foregoing embodiments, although the description has been given as to the case where the size of the lower layer FG is at least partially smaller than the size of the upper layer FG in one of the column direction and the row direction. However, the present invention is not restricted thereto, and it is possible to adopt a conformation that the size of the lower layer FG is at least partially smaller than the size of the upper layer FG in both the column direction and the row direction as a matter of course. As a manufacturing method in this case, it is possible to use a combination of the third embodiment and the first and second embodiments, and a combination of the fourth embodiment and the first and second embodiments.

Further, although the semiconductor substrate has been described as the substrate, but the present invention is not restricted thereto, and it is also possible to form the memory according to each of the foregoing embodiments on, e.g., a glass substrate or a ceramic substrate as long as the substrate has a semiconductor layer formed on a front surface.

Furthermore, in the foregoing embodiments, although the description has been given as to the case where the tunnel insulating film and the floating gate are laminated on the substrate twice and the memory cell is thereby formed. However, the number of times of performing the lamination is not restricted to two, and the lamination may be carried out more than twice in order to form the memory cell. In this case, a dimension of a floating gate in a first layer which is the lowest layer is at least partially smaller than a dimension of a floating gate in a second layer (N=2).

The accompanying claims and their equivalents are intended to cover the above mentioned forms or modifications as would fall within the scope and spirit of the inventions.

1. A semiconductor memory device comprising:
a substrate comprising a semiconductor layer on a surface thereof; and
a plurality of memory cells,
wherein each the memory cell comprises:
a laminated body with a tunnel insulating film and a floating gate on the tunnel insulating film being sequentially laminated on the semiconductor layer in a direction vertical to the surface of the substrate for N (a natural number equal to or above 2) times;
a gate insulating film on the laminated body; and
a control gate on the gate insulating film, and
a dimension of the floating gate in the lowermost layer is at least partially smaller than a dimension of the floating gate in each of second and subsequent layers in at least one of a first direction parallel to the surface of the substrate and a second direction crossing the first direction.

2. The device of claim 1,
wherein opposed surfaces of the floating gate in the lowermost layer and the floating gate in the second layer have the same size.

3. The device of claim 2,
wherein a size of a surface of the floating gate in the second layer facing the substrate is smaller than a size of a surface of the floating gate in the second layer on the gate insulating film side.

4. The device of claim 1,
wherein a size of a surface of the floating gate in the lowermost layer facing the substrate is smaller than a size of a surface of the floating gate in the second layer facing the substrate.

5. The device of claim 4,
wherein the size of the surface of the floating gate in the lowermost layer facing the substrate is smaller than a size of a surface of the floating gate in the lowermost layer on the same side as the floating gate in the second layer.

6. The device of claim 1,
wherein a sidewall of the floating gate in each of the second and subsequent layers is made of an oxidation-resistant material.

7. The device of claim 1, further comprising an insulating film which is formed on a sidewall of each floating gate in the second or subsequent layer between the memory cells and extends to a side surface of the control gate.

8. The device of claim 1, further comprising an insulating film in which a cavity is provided in a region between the memory cells.

9. A manufacturing method of a semiconductor memory device, comprising:
sequentially forming a first insulating film, a first floating gate material, a second insulating film, and a second floating gate material on a front surface of a semiconductor layer on or of a substrate, performing selective removal based on first patterning using a resist, and forming a line-and-space pattern in which lines are apart from each other at predetermined intervals in a first direction parallel to the front surface of the substrate as a longitudinal direction of the lines;
forming a shallow trench isolation insulating film in a space region of the line-and-space pattern, thereby defining an active region;
sequentially forming a third insulating film and a conductive film, performing selective removal based on second patterning using a resist, and forming a gate insulating film and a control gate in a second direction crossing the first direction as a longitudinal direction of the gate insulating film and the control gate;
oxidizing a side surface parallel to at least one of the first and second directions in side surfaces of the first and second insulating films; and
forming an impurity diffusion layer in the active region, wherein a material of the second insulating film has stronger oxidation resisting properties than a material of the first insulating film.

10. The method of claim 9,
wherein the line-and-space pattern is removed by the first patterning until any depth in a range from an upper end of the second insulating film and a lower end of the first insulating film is reached in a direction vertical to the front surface of the substrate.

11. The method of claim 9, further comprising forming an insulating film in a space between cells so as to include a cavity therein.

12. A manufacturing method of a semiconductor memory device, comprising:
sequentially forming a first insulating film, a first floating gate material, a second insulating film, and a second floating gate material on a front surface of a semiconductor layer on or of a substrate, performing selective removal based on first patterning using a resist, and forming a line-and-space pattern comprising a first tunnel insulating film, a first floating gate, a second tunnel insulating film, and a second floating gate in which lines are apart from each other at predetermined intervals in a first direction parallel to the front surface of the substrate as a longitudinal direction of the lines;
forming a shallow trench isolation insulating film in a space region of the line-and-space pattern, thereby defining an active region;
sequentially forming a third insulating film and a conductive film, performing selective removal based on second patterning using a resist, and forming a gate insulating film and a control gate in a second direction crossing the first direction as a longitudinal direction of the gate insulating film and the control gate;
forming a fourth insulating film having oxidation resisting properties on a sidewall of the second floating gate along at least one of the first and second directions; and
oxidizing a side surface of the first tunnel insulating film along the fourth insulating film so as to be thicker than the fourth insulating film.

13. The method of claim 12,
wherein the second patterning comprises stopping etching in a range between an upper end of the second floating gate and a lower end of the first floating gate.

14. The method of claim 13,
wherein the etching is stopped between the upper end and the lower end of the second floating gate.

15. The method of claim 13,
wherein the etching is stopped between an upper end and a lower end of the second insulating film.

16. The method of claim 13,
wherein the etching is stopped between the upper end and the lower end of the first floating gate.

17. The method of claim 12,
wherein the fourth insulating film is formed so as to extend to a side surface of the control gate.

18. The method of claim 12,
wherein the fourth insulating film is formed before formation of the third insulating film and the conductive film.

19. The method of claim 12,
wherein the fourth insulating film is formed after formation of the gate insulating film and the control gate.

20. The method of claim 12, further comprising forming an insulating film in a space between cells so as to include a cavity therein.
